(19) United States
(12) Patent Application Publication
(10) Pub. No.: US 2015/0349741 A1
(43) Pub. Date: Dec. 3, 2015

(54) TEMPERATURE COMPENSATED CIRCUITS FOR RADIO-FREQUENCY DEVICES

(71) Applicant: SKYWORKS SOLUTIONS, INC., Woburn, MA (US)

(72) Inventors: Philip John LEHTOLA, Cedar Rapids, IA (US); Andrew Martin KAY, Lake Forest, CA (US)

(21) Appl. No.: 14/725,103

(22) Filed: May 29, 2015

Related U.S. Application Data
(60) Provisional application No. 62/004,792, filed on May 29, 2014.

(51) Int. Cl. H03H 7/40; H03F 3/24; H03F 3/195; H01Q 1/50; H03F 1/56

(52) U.S. Cl. CPC H03H 7/40; H01Q 1/50; H03F 1/56; H03F 3/195; H03F 3/245; H03F 2200/451; H03F 2200/387

(57) ABSTRACT

Temperature compensated circuits for radio-frequency (RF) devices. In some embodiments, an RF circuit can include an input node and a plurality of components interconnected to the input node and configured to yield an impedance for an RF signal at the input node. At least one of the plurality of components can be configured to have temperature-dependence within a temperature range so that the impedance varies to compensate for an effect of temperature change. Such an RF circuit can be, for example, an impedance matching circuit implemented at an output of a power amplifier. The component having temperature-dependence can include a temperature-dependent capacitor such as a ceramic capacitor.

### CROSS-REFERENCE TO RELATED APPLICATION(S)

This application claims priority to U.S. Provisional Application No. 62/004,792 filed May 29, 2014, entitled TEMPERATURE COMPENSATED CIRCUITS FOR RADIO-FREQUENCY DEVICES, the disclosure of which is hereby expressly incorporated by reference herein in its entirety.

### BACKGROUND

1. Field

The present disclosure relates to temperature compensated circuits for radio-frequency (RF) applications.

2. Description of the Related Art

In radio-frequency (RF) applications, various circuits can be implemented to process an RF signal. For example, a transceiver can generate an RF signal which is then amplified for transmission. The amplified RF signal is typically passed through circuits such as an impedance matching circuit, a filter circuit, and a switching circuit, so as to be delivered to an antenna to be radiated wirelessly.

### SUMMARY

In some implementations, the present disclosure relates to a radio-frequency (RF) circuit that includes an input node and a plurality of components interconnected to the input node and configured to yield an impedance for an RF signal at the input node. At least one of the plurality of components is configured to have temperature-dependence within a temperature range so that the impedance varies to compensate for an effect of temperature change.

In some embodiments, the RF circuit can include an impedance matching circuit. The RF circuit can further include an output node configured to be connectable to a load. The impedance matching circuit can include a power amplifier (PA) output matching circuit, and the load can include an antenna. The PA output matching circuit can include a first L-section having a first inductance between the input node and the output node, and a first capacitive shunt implemented between a node adjacent the first inductance and a ground. The first capacitive shunt can include a temperature-dependent capacitor configured to provide the temperature-dependence within the temperature range. The node adjacent the first inductance can be a node after the first inductance.

The PA output matching circuit can further include a second L-section having a second inductance in series with the first inductance, and a second capacitive shunt implemented between a node adjacent the second inductance and the ground. The second capacitive shunt can include a capacitor. The node adjacent the second inductance can be a node after the second inductance. The capacitor of the second capacitive shunt can be a non-temperature dependent capacitor. The first L-section and the second L-section can be arranged to form a two-stage L-section configuration.

In some embodiments, the temperature-dependent capacitor can include a ceramic capacitor.

In some embodiments, the ceramic capacitor can be configured so that its capacitance increases with an increase in temperature. The capacitance can increases by about 13 to 15% when the temperature range is approximately 25° C. to 85° C. The ceramic capacitor can include a ceramic block with a dielectric constant in a range of 4,500 to 7,000. The ceramic capacitor can have an X7R rating. The ceramic capacitor can be a surface mount device having a 0201 form factor. The capacitance can vary in a range having an upper limit that is less than about 50 pF or about 20 pF.

In some embodiments, the increase in capacitance can result in a decrease in the impedance of the circuit. The impedance can have a value of approximately 4.5 Ohms at a temperature of 25° C. The impedance can decrease to approximately 4.0 Ohms at a temperature of 85° C.

In some embodiments, the effect of temperature change can include a degradation in a power saturation level at a higher temperature, and the decrease in impedance can be selected to increase the power saturation level to compensate for the degradation. The power saturation level can be increased by about 0.5 dB at the higher temperature to maintain an acceptable linearity at or near the power saturation level.

In accordance with a number of implementations, the present disclosure relates to a radio-frequency (RF) module that includes a packaging substrate configured to receive a plurality of components, and a die mounted on the packaging substrate and having a power amplifier circuit configured to generate an amplified RF signal at its output node. The RF module further includes a matching circuit implemented on the packaging substrate and connected to the output node of the power amplifier circuit. The matching circuit is configured to provide impedance-matching for the amplified RF signal and includes at least one component configured to have temperature-dependence within a temperature range so that an impedance associated with the matching circuit varies to compensate for an effect of temperature change on the amplified RF signal. The RF module further includes a plurality of connectors configured to provide electrical connections between the power amplifier circuit, the matching circuit, and the packaging substrate. In some embodiments, the at least one temperature-dependent component can include a temperature-dependent capacitor.

According to some teachings, the present disclosure relates to a radio-frequency (RF) device that includes a transceiver configured to process RF signals, and an antenna in communication with the transceiver and configured to facilitate transmission of an amplified RF signal. The RF device further includes a power amplifier circuit connected to the transceiver and configured to generate the amplified RF signal. The RF device further includes a matching circuit implemented between the power amplifier circuit and the antenna, and configured to provide impedance-matching for the amplified RF signal. The matching circuit includes at least one component configured to have temperature-dependence within a temperature range so that an impedance associated with the matching circuit varies to compensate for an effect of temperature change on the amplified RF signal.

In some embodiments, the RF device can include a wireless device. At least one temperature-dependent component can include a temperature-dependent capacitor.

In a number of implementations, the present disclosure relates to a temperature-dependent capacitor that includes a ceramic block having a dielectric constant between 4,500 and 7,000. The temperature-dependent capacitor further includes first and second electrodes disposed about the ceramic block. The ceramic block and the electrodes can be configured to provide temperature-dependent capacitance in a range that is less than about 50 pF.

In some embodiments, the capacitance can vary by about 13-15% within a temperature range of about 60 degrees in Celsius, such as between 25° C. and 85° C. The ceramic block can be substantially free of internal electrodes. The capacitor can have a 0201 SMD form factor and an X7R performance rating.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts a block diagrams of a temperature-compensated circuit having one or more features as described herein.

FIGS. 2A and 2B show an example situation where an impedance matching circuit can be utilized.

FIG. 3 shows plots of a power amplifier's measured adjacent channel leakage ratio (ACLR) values as a function of measured output power operated at an example frequency and at different temperatures.

FIG. 4 shows the same data set of FIG. 3 presented so that the ACLR values are plotted versus output power normalized to maximum saturated output power (Psat).

FIG. 5 shows examples of power added efficiency (PAE) curves as a function of output power for a given Psat and an overhead-added Psat, showing that PAE can be degraded when Psat overhead is added.

FIG. 6A shows an example matching circuit that can utilize a capacitor having temperature-dependent capacitance Ctemp.

FIG. 6B shows that the example matching circuit of FIG. 6A can be configured so that given an external load impedance of Z_{Load} on the RF_out side, the matching circuit presents an impedance of Z on the RF_in side.

FIG. 7 shows a Smith plot of an example effect of the change in capacitance induced by temperature change.

FIG. 8 shows a plot of a reduction in load line impedance as temperature-induced capacitance increases.

FIGS. 9A and 9B show different views of a temperature-dependent capacitor that can be implemented as a ceramic capacitor.

FIGS. 10A and 10B show different views of an example module having a temperature-compensated circuit.

FIG. 11 shows an example wireless device having one or more advantageous features as described herein.

### DETAILED DESCRIPTION OF SOME EMBODIMENTS

The headings provided herein, if any, are for convenience only and do not necessarily affect the scope or meaning of the claimed invention.

Disclosed herein are apparatus and methods related to a temperature-compensated circuit that utilizes one or more components whose performance depends on temperature. FIG. 1 depicts a block diagrams of a temperature-compensated circuit 100 that can be configured to provide one or more desired functionalities between first (e.g., an input) and second (e.g., an output) nodes (1 and 2).

In some embodiments, a temperature-compensated circuit can be implemented as an impedance matching circuit. It will be understood that, although various features and advantages are described herein in the context such a matching circuit, one or more features of the present disclosure can also be implemented in other types of radio-frequency (RF) or RF-related circuits.

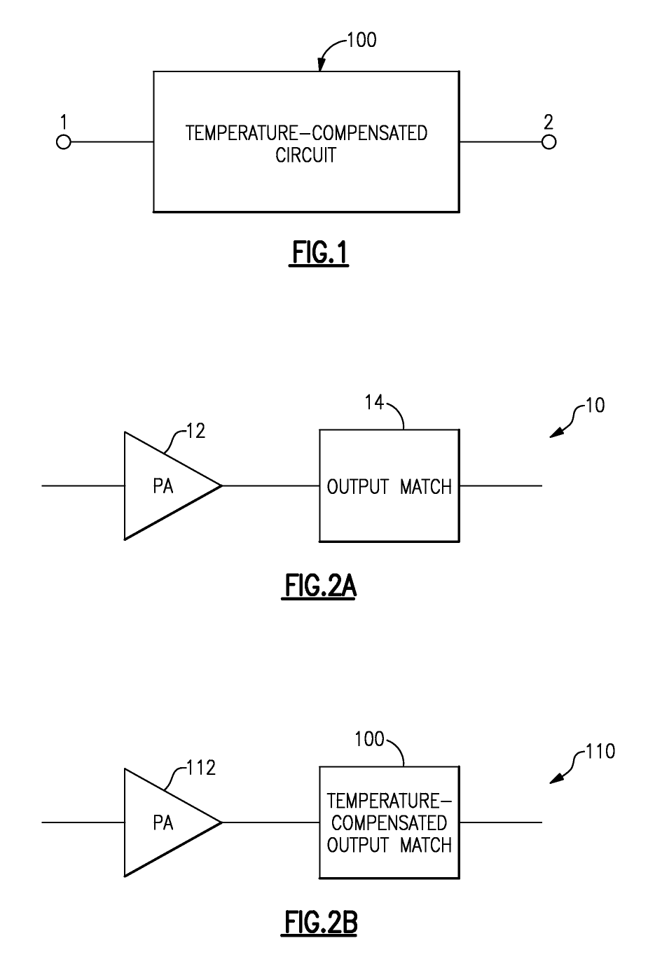

FIGS. 2A and 2B show an example situation where an impedance matching circuit can be utilized. In an example configuration 10 of FIG. 2A, an output matching circuit 14 without a temperature-compensating feature is shown to provide impedance matching of an output RF signal of a power amplifier (PA) 12 with an electrical load (not shown) (e.g., an antenna) to increase or maximize power transfer and/or to reduce or minimize reflections from the load.

In an example configuration 110 of FIG. 2B, an output matching circuit 100 having a temperature-compensating feature is shown to provide impedance matching of an output radio-frequency (RF) signal of a power amplifier (PA) 112 with an electrical load (e.g., an antenna). As described herein, such a temperature-compensating feature can facilitate improved performance associated with the PA 112.

In power amplifier (PA) designs for RF applications, a number of performance features can be considered. For example, in the context of linear PAs, there is typically an important tradeoff between efficiency and adjacent channel leakage ratio (ACLR) (or linearity). A PA is typically more efficient when operated near saturation. However, a PA is typically more linear (e.g., has better ACLR performance) when operated away from saturation. Thus, a typical PA design can be configured to operate very close to saturation to meet a desired linearity requirement while providing relatively high efficiency.

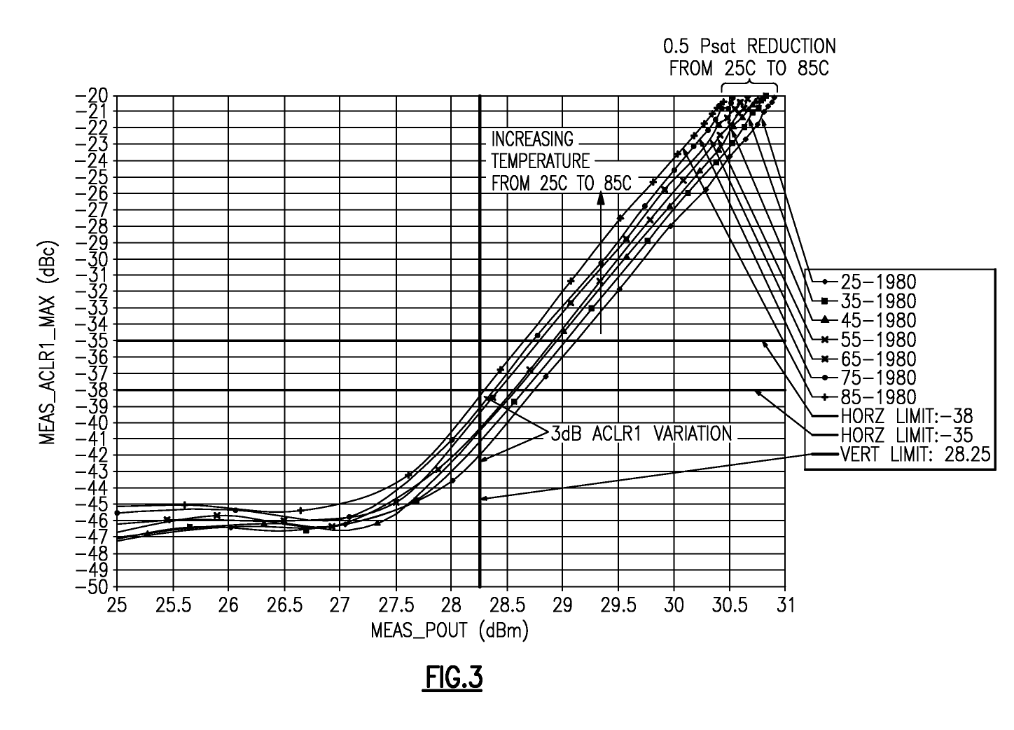

When a PA is operated very close to saturation, a small variation in temperature can yield a significant change in linearity. Such a change can lead to significant degradation in linearity performance. For example, FIG. 3 shows plots of a PA's measured ACLR1s as a function of measured output power operated at approximately 1.980 GHz and at different temperatures (approximately 25° C., 35° C., 45° C., 55° C., 65° C., 75° C. and 85° C.). The example plots show that as temperature is increased from 25° C. to 35° C., ACLR1 degrades by about 3 dB. The example plots also show that as temperature is increased from 25° C. to 35° C., the saturation power (Psat) is reduced by about 0.5 dB.

It is believed that the ACLR1 degradation results from the change (e.g., reduction by 0.5 dB) in the maximum saturated output power (Psat) of the amplifier. Such a reduction in Psat is believed to result from increased losses associated with some or all of wiring, interconnect and/or passives, and increased Vce,sat of transistors with temperature.

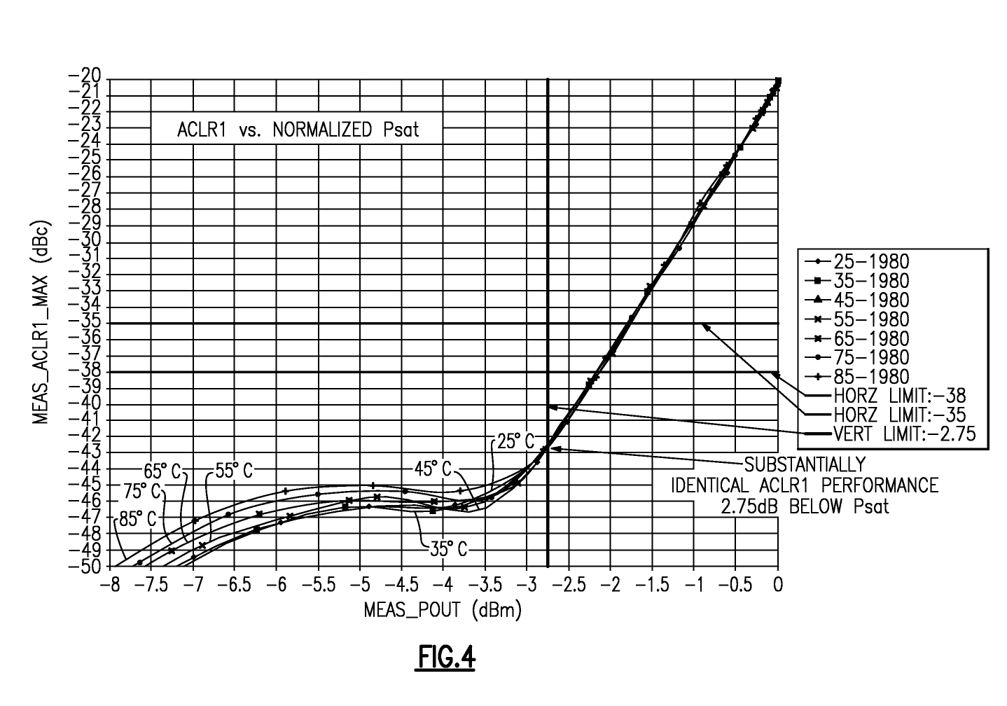

The foregoing observation can be confirmed in FIG. 4, where the same data set of FIG. 3 is presented so that ACLR1s are plotted versus output power normalized to Psat. The plots in FIG. 4 show that ACLR1 performances are substantially identical to about 2.75 dB below Psat. This shows that the ACLR1 degradation with temperature is substantially or completely a function of Psat drift.

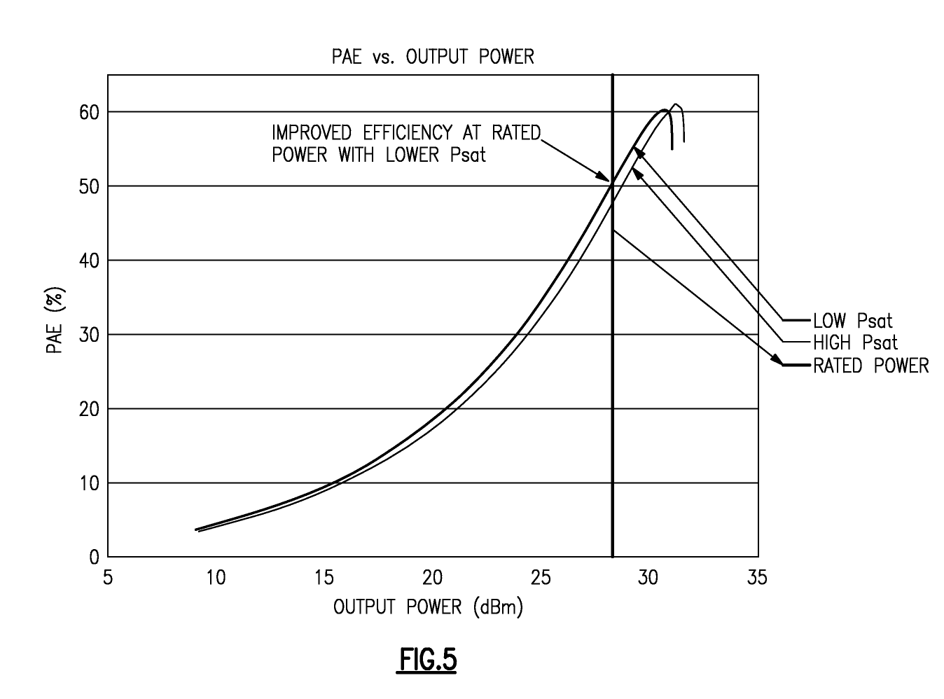

In some situations, the foregoing performance degradation due to temperature change can be addressed by designing a load line with enough overhead power to support ACLR and/or gain at, for example, high temperatures. For example, such an overhead can be configured to provide about 0.5 dB more power than what is necessary at room temperature. However, and as shown in FIG. 5, designing for additional overhead power can degrade the power added efficiency (PAE). In FIG. 5 two curves (PAE versus output power) representative of a given Psat (“Low Psat”) and an overhead-added Psat (“High Psat”) are shown. The “Low Psat” configuration is shown to have a generally higher PAE than that of the overhead-added (High Psat) configuration.

In some implementations, temperature-related performance changes such as the foregoing examples of performance degradation can be compensated by a matching circuit, without having to rely on the addition of overhead power. In some embodiments, such temperature-compensation can be achieved by use of one or more temperature-dependent components. By selecting, among others, a desired temperature dependence of such component(s), desired temperature-compensation characteristics of a circuit (e.g., a matching circuit) can be implemented.

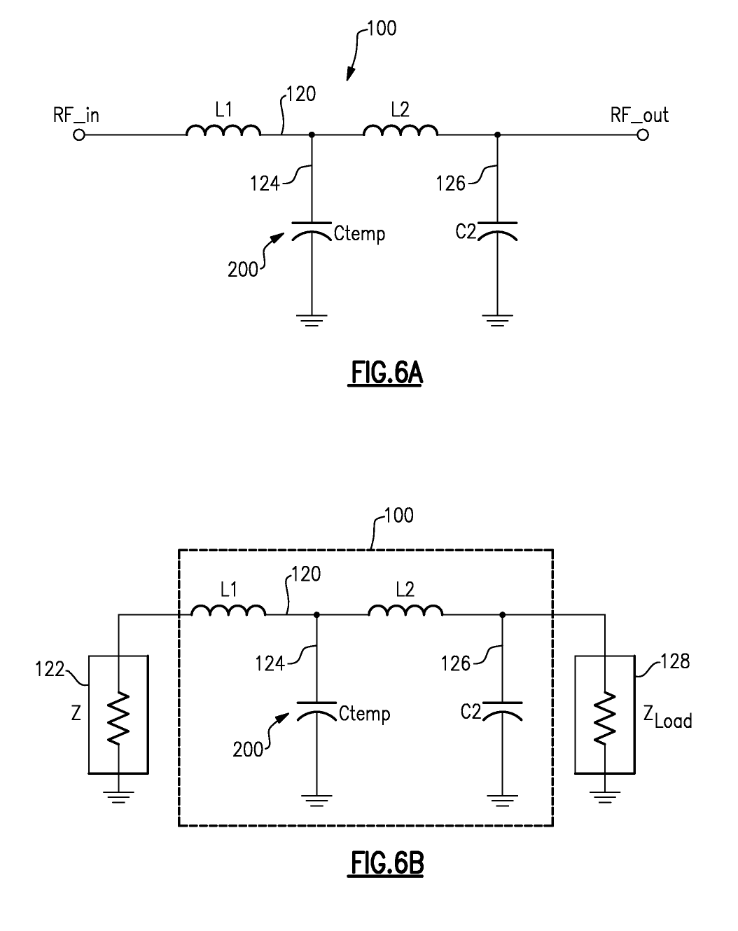

FIG. 6A shows an example matching circuit 100 that utilizes a capacitor 200 having temperature-dependent capacitance Ctemp. Additional details about such a capacitor are described herein in greater detail. It will be understood that such a temperature-dependent capacitor can also be utilized in other types of matching circuits. It will also be understood that other temperature-dependent components can also be utilized to yield desired performance characteristics of matching circuits.

FIG. 6B shows that the example matching circuit 100 of FIG. 6A can be configured so that given an external load impedance of Z_{Load} (depicted as 128) on the RF_out side, the matching circuit 100 presents an impedance of Z (depicted as 122) on the RF_in side. Thus, by way of an example, if RF_in is connected to an output of a power amplifier (PA) (e.g., 112 in FIG. 2B), the PA is presented with an impedance of Z instead of Z_{Load} to, for example, desirably impedance-match the PA output.

In the example matching circuit 100, a path 120 between RF_in and RF_out is shown to include first and second inductances L1, L2. In some embodiments, such inductances can be provided by, for example, discrete inductors, wire connections, conductor traces, or any combination thereof.

The example matching circuit 100 is also shown to include a first capacitive shunt branch 124 implemented between L1 and L2 and coupled to the ground via a first capacitance (e.g., a capacitor) 200. In the example described herein, the first capacitor 200 can be a temperature-dependent capacitor having capacitance Ctemp that varies with temperature. A second capacitive shunt branch 126 is shown to be implemented to couple the output node RF_out (e.g., downstream of L2) to the ground via a second capacitance (e.g., a capacitor) C2.

Table 1 lists example values that can be implemented for the foregoing components to achieve an example temperature-compensation described herein. The values listed are approximate. Other values can also be used.

TABLE 1

| Component | Approximate value | |
|---|---|---|
| Effective Z | 4.5 | Ohms |
| Effective Z_{Load} | 50 | Ohms |
| L1 | 0.323 | nH |
| L2 | 1.496 | nH |
| Ctemp | 9 pF to 10.2 pF | |
| C2 | 3.75 | pF |

In the context of the example configuration associated with FIGS. 6A and 6B and Table 1, approximately 2-3% higher PAE can be achieved for a power amplifier (e.g., for Band 1 of a high efficiency WCDMA module) by providing an extra output power of about 0.5 dB at high temperature (e.g., 85° C., versus lower temperature such as 25° C.) for linearity compensation. Such an effect can be achieved by reducing a load line impedance from approximately 4.5 Ohms to approximately 4.0 Ohms. The 4.5 Ohm load line impedance can be achieved with the temperature-dependent Ctemp having a value of approximately 9 pF at the lower temperature of 25° C. The 4.0 Ohm load line impedance can be achieved with the temperature-dependent Ctemp having a value of approximately 10.2 pF at the higher temperature of 85° C.

In some embodiments, a capacitor that can provide the foregoing example temperature-dependent capacitance Ctemp can include relatively high Q and relatively tight tolerance properties. For example, there are temperature-dependent capacitors that have relatively large tolerances (e.g., +/−15%) and having capacitance values between about 100 to 10⁶ pF. Such capacitors will likely not be useful for the example temperature-compensated match circuit described in reference to FIGS. 6A and 6A and Table 1 due to, for example, capacitance values and tolerances being too large. However, such temperature-dependent capacitors may be utilized in other RF applications.

In some embodiments, a capacitor that can be utilized for facilitating temperature compensation of an RF PA output matching circuit can include a temperature-dependent capacitor having a tolerance of approximately 10% or less, or more preferably 5% or less. In some embodiments, such a tolerance can be in a range of approximately 3% to 5%. Such a capacitor can have a capacitance value that is, for example, less than 100 pF, less than 80 pF, less than 60 pF, less than 50 pF, less than 40 pF, less than 30 pF, less than 20 pF, or less than 15 pF in its operating temperature range.

In some embodiments, capacitance value of a temperature-dependent capacitor having one or more features as described herein can increase as temperature increases. In the example temperature range of 25° C. to 85° C. described herein, the capacitance value can change by about 13-15%. It will be understood that other operating ranges of temperature and/or relative changes are also possible. It will also be understood that temperature-dependence in which capacitance increases with temperature, decreases with temperature, or any combination thereof (e.g., capacitance increases in one range of temperature and decreases in another range of temperature) can be utilized in a temperature-dependent capacitor and related RF circuit(s).

In some embodiments, a temperature-dependent capacitor having one or more features as described herein can have a Q value of, for example, at least 100 at 1 GHz. In a more specific example, a Q value of at least 180 can be desirably high for the capacitor's reactance at a capacitance value of approximately 9 pF. It will be understood that other values or ranges of Q and/or capacitance can also be implemented.

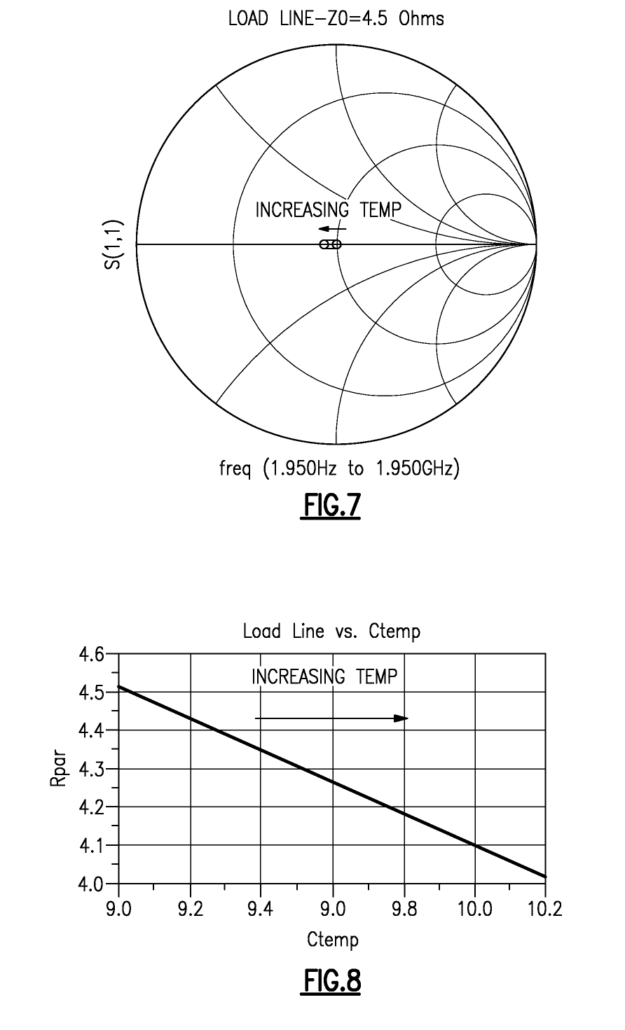

FIGS. 7 and 8 show example effects of the change in capacitance induced by temperature change (e.g., 25° C. to 85° C.). FIG. 7 shows a Smith chart, where an S1,1 scattering parameter is shown to decrease as temperature increases. FIG. 8 shows a plot of the above-described reduction in load line impedance from approximately 4.5 Ohms to approximately 4.0 Ohms as temperature-induced capacitance increases from approximately 9.0 pF to approximately 10.2 pF.

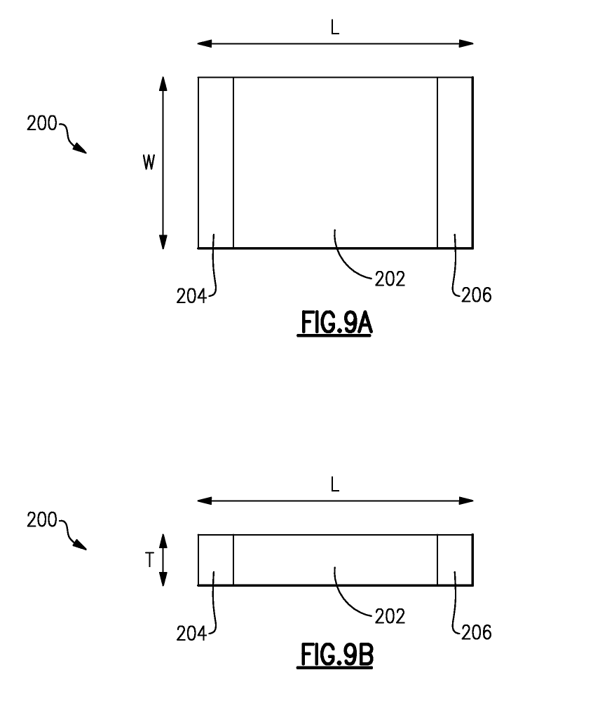

In some embodiments, a temperature-dependent capacitor having some or all of the features described herein can be implemented as a ceramic capacitor. FIGS. 9A and 9B show plan and side views of an example ceramic capacitor 200 having overall dimensions of L (length), width (W) and thickness (T). The capacitor 200 can include a ceramic dielectric block 202 disposed between first and second electrodes 204, 206.

In some embodiments, the foregoing ceramic capacitor 200 can be implemented as, for example, a 0201 sized surface-mount device (SMD) with a footprint size of approximately 0.6 mm×0.3 mm. Other sizes and/or configurations are also possible.

In some embodiments, the foregoing ceramic block 202 can be configured to provide bulk dielectric constant in a range of, for example, about 4,500 and 7,000. Other ranges of bulk dielectric constant can also be used.

The ceramic block 202 can be configured to provide, for example, X7R temperature characteristics (low temperature of −55° C., high temperature of +125° C., and capacitance change of +/−15%). Other temperature characteristics can also be utilized. For example, “Y” (low temperature of −30° C.) or “Z” (low temperature of +10° C.) configuration can also be used in some situations. For high temperature, “6” (high temperature of +105° C.) or “8” (high temperature of +150° C.) configuration can also be used in some situations. For relative capacitance change, other ranges such as “P” (+/−10%) or “S” (+/−22%) can also be used in some situations. Other configurations can also be utilized.

In some embodiments, the foregoing example ceramic capacitor 200 can be implemented with standard external cap electrodes, and without inner electrodes. Other electrode configurations can also be implemented.

As described herein, one or more temperature-dependent capacitors can be utilized in RF circuits such as an example impedance matching circuit 100 of FIGS. 6A and 6B to obtain desirable performance benefits. In the example of FIGS. 6A and 6B, the impedance matching circuit 100 generally has a two-stage L-section configuration. It will be understood that such a configuration is an example of an impedance matching circuit. Accordingly, one or more temperature-dependent capacitors can be utilized in other types of impedance matching circuits.

It will also be understood that impedance matching circuits having one or more features as described herein are examples of RF circuits that can include one or more temperature-dependent capacitors. Accordingly, one or more temperature-dependent capacitors can be utilized in other types of RF circuits. For example, an RF circuit can have a frequency response and/or a resonance that depend on a capacitance value of a capacitor; and performance related to such an RF circuit can be sensitive to relatively small variations in the frequency response and/or the resonance. Accordingly, use of one or more temperature-dependent capacitors in such an RF circuit can compensate for undesirable temperature-related effects.

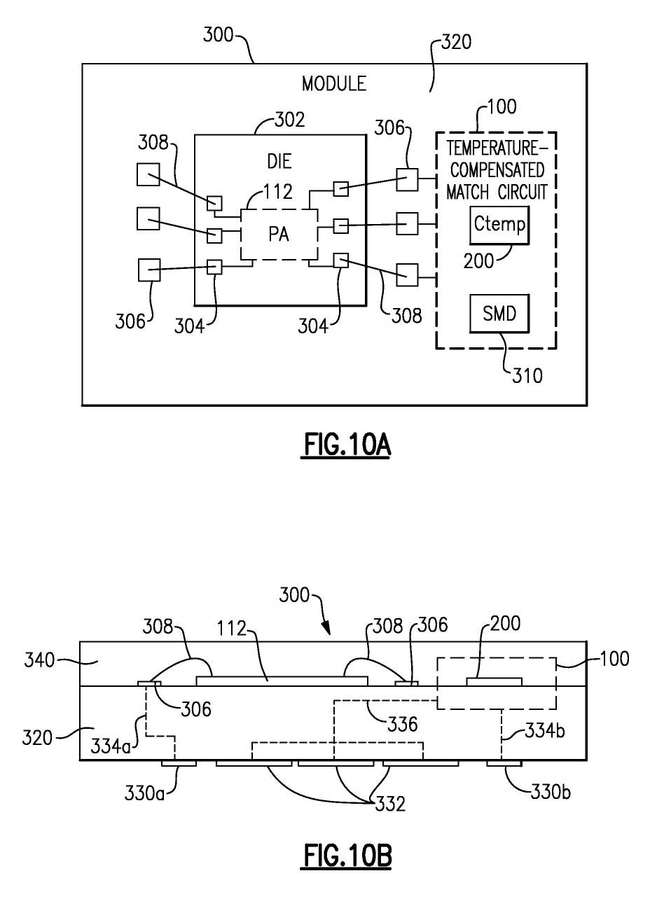

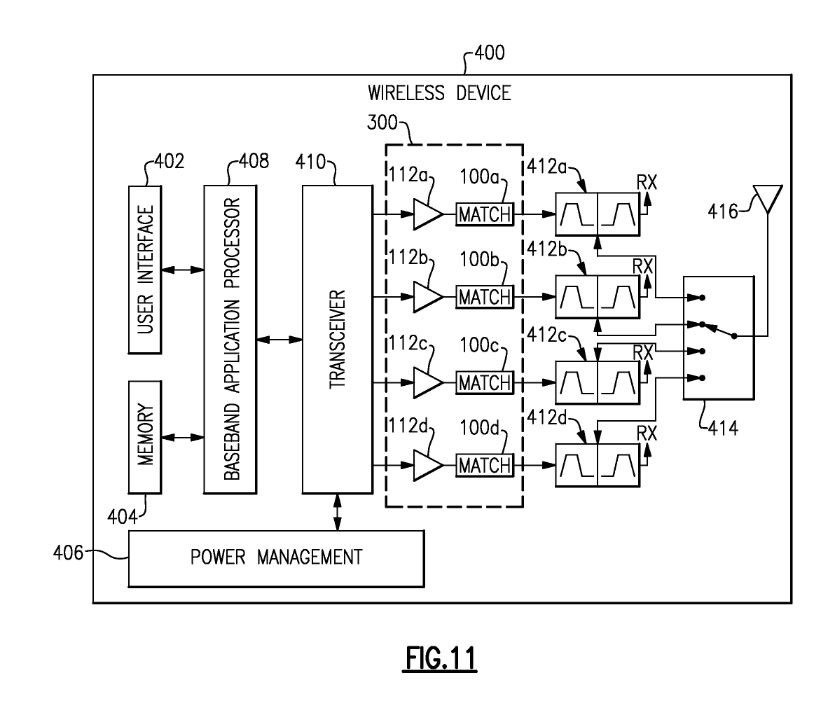

In some implementations, a device and/or a circuit having one or more features described herein can be included in a module. An example of such a module (300) is depicted in FIGS. 10A (a plan view) and 10B (a side view).

In the example context of the output matching of amplified RF signals, the example module 300 is shown to include a die 302 having a power amplifier circuit 112 as described herein. Such a die can be fabricated using a number of semiconductor process technologies. The die 302 can include a plurality of electrical contact pads 304 configured to allow formation of electrical connections 308 such as wirebonds between the die 302 and contact pads 306 formed on a packaging substrate 320 of the module 300.

In the example module 300, the packaging substrate 320 can be configured to receive a plurality of components such as the die 302 and one or more SMDs (e.g., 310). In some embodiments, the packaging substrate 320 can include, for example, a laminate substrate, a ceramic substrate, etc.

The module 300 is shown to include a temperature-compensated match circuit 100 having one or more features described herein. Such a circuit can include a temperature-dependent capacitor 200 and one or more additional SMDs (e.g., non-temperature-dependent capacitor(s) and resistor(s)). In some embodiments, inductances associated with the circuit 100 can be provided by discrete inductors and/or conductor paths associated with the circuit 100. In some embodiments, some of such conductor paths can be located below the surface of the packaging substrate 320. Accordingly, the circuit 100 can be on the surface of the packaging substrate 320; and in some situations, can extend into a portion of the substrate 320.

The module 300 is shown to include a plurality of contact pads 330, 332 disposed on the side opposite from the side where the die 112 is mounted on. Such a configuration can allow easy mounting of the module 300 on a circuit board such as a phone board of a wireless device. The example contact pads 332 can be configured to provide a ground connection. The example contact pads 330 can be configured to provide connections for power and RF signals. For example, the example contact pads 330a and 330b can provide input and output connections for RF signals into and out of the PA 112.

In some embodiments, the module 300 can also include one or more packaging structures to, for example, provide protection and facilitate easier handling of the module 300. Such a packaging structure can include an overmold 340 formed over the packaging substrate 320 and dimensioned to substantially encapsulate the various circuits thereon.

It will be understood that although the module 300 is described in the context of wirebond-based electrical connections, one or more features of the present disclosure can also be implemented in other packaging configurations, including flip-chip configurations.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 11 depicts an example wireless device 400 having one or more advantageous features described herein. In the context of an output match circuit for a PA, a plurality of match circuits 100a, 100b, 100c, 100d having one or more features described herein are shown to be connected to outputs of their respective PAs 112a, 112b, 112c, 112d. Such PAs can facilitate, for example, multi-band operation of the wireless device 400. In embodiments where the PAs and their matching circuits are packaged into a module, such a module can be represented by a dashed box 300.

The PAs 112 can receive their respective RF signals from a transceiver 410 that can be configured and operated in known manners to generate RF signals to be amplified and transmitted, and to process received signals. The transceiver 410 is shown to interact with a baseband application processor 408 that is configured to provide conversion between data and/or voice signals suitable for a user and RF signals suitable for the transceiver 410. The transceiver 410 is also shown to be connected to a power management component 406 that is configured to manage power for the operation of the wireless device. Such power management can also control operations of the baseband application processor 408 and the PA module 300.

The baseband application processor 408 is shown to be in communication with a user interface 402 to facilitate various input and output of voice and/or data provided to and received from the user. The baseband application processor 408 can also be in communication with a memory 404 that is configured to store data and/or instructions to facilitate the operation of the wireless device, and/or to provide storage of information for the user.

In the example wireless device 400, outputs of the match circuits (100a-100d) are shown to be routed to an antenna 416 via their respective duplexers 412a-412d and a band-selection switch 414. The band-selection switch 414 can include, for example, a single-pole-multiple-throw (e.g., SP4T) switch to allow selection of an operating band (e.g., Band 2). In some embodiments, each duplexer 412 can allow transmit and receive operations to be performed simultaneously using a common antenna (e.g., 416). In FIG. 11, received signals are shown to be routed to “Rx” paths (not shown) that can include, for example, a low-noise amplifier (LNA).

A number of other wireless device configurations can utilize one or more features of the temperature-compensated match circuit described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A radio-frequency (RF) circuit comprising:
an input node;
a plurality of components interconnected to the input node and configured to yield an impedance for an RF signal at the input node;
at least one of the plurality of components configured to have temperature-dependence within a temperature range so that the impedance varies to compensate for an effect of temperature change.

2. The RF circuit of claim 1 wherein the RF circuit includes an impedance matching circuit.

3. The RF circuit of claim 2 further comprising an output node configured to be connectable to a load.

4. The RF circuit of claim 3 wherein the impedance matching circuit includes a power amplifier (PA) output matching circuit, and the load includes an antenna.

5. The RF circuit of claim 4 wherein the PA output matching circuit includes a first L-section having a first inductance between the input node and the output node, and a first capacitive shunt implemented between a node adjacent the first inductance and a ground, the first capacitive shunt including a temperature-dependent capacitor configured to provide the temperature-dependence within the temperature range.

6. The RF circuit of claim 5 wherein the node adjacent the first inductance is a node after the first inductance.

7. The RF circuit of claim 5 wherein the PA output matching circuit further includes a second L-section having a second inductance in series with the first inductance, and a second capacitive shunt implemented between a node adjacent the second inductance and the ground, the second capacitive shunt including a capacitor.

8. The RF circuit of claim 7 wherein the node adjacent the second inductance is a node after the second inductance.

9. The RF circuit of claim 7 wherein the capacitor of the second capacitive shunt is a non-temperature dependent capacitor.

10. The RF circuit of claim 7 wherein the first L-section and the second L-section are arranged to form a two-stage L-section configuration.

11. The RF circuit of claim 5 wherein the temperature-dependent capacitor includes a ceramic capacitor.

12. The RF circuit of claim 11 wherein the ceramic capacitor is configured so that its capacitance increases with an increase in temperature.

13. The RF circuit of claim 12 wherein the capacitance increases by about 13 to 15% when the temperature range is approximately 25° C. to 85° C.

14. The RF circuit of claim 12 wherein the capacitance varies in a range having an upper limit that is less than about 50 pF.

15. The RF circuit of claim 12 wherein the increase in capacitance results in a decrease in the impedance of the circuit.

16. The RF circuit of claim 15 wherein the effect of temperature change includes a degradation in a power saturation level at a higher temperature, and the decrease in impedance is selected to increase the power saturation level to compensate for the degradation.

17. The RF circuit of claim 16 wherein the power saturation level is increased by about 0.5 dB at the higher temperature to maintain an acceptable linearity at or near the power saturation level.

18. A radio-frequency (RF) module comprising:
a packaging substrate configured to receive a plurality of components;
a die mounted on the packaging substrate and having a power amplifier circuit configured to generate an amplified RF signal at its output node;
a matching circuit implemented on the packaging substrate and connected to the output node of the power amplifier circuit, the matching circuit configured to provide impedance-matching for the amplified RF signal and including at least one component configured to have temperature-dependence within a temperature range so that an impedance associated with the matching circuit varies to compensate for an effect of temperature change on the amplified RF signal; and
a plurality of connectors configured to provide electrical connections between the power amplifier circuit, the matching circuit, and the packaging substrate.

19. The RF module of claim 18 wherein the at least one temperature-dependent component includes a temperature-dependent capacitor.

20. A radio-frequency (RF) device comprising:
a transceiver configured to process RF signals;
an antenna in communication with the transceiver and configured to facilitate transmission of an amplified RF signal;
a power amplifier circuit connected to the transceiver and configured to generate the amplified RF signal; and
a matching circuit implemented between the power amplifier circuit and the antenna, and configured to provide impedance-matching for the amplified RF signal, the matching circuit having at least one component configured to have temperature-dependence within a temperature range so that an impedance associated with the matching circuit varies to compensate for an effect of temperature change on the amplified RF signal.
